(19) United States
(12) Patent Application Publication
(10) Pub. No.: US 2026/0040939 A1
(43) Pub. Date: Feb. 5, 2026

(54) RIVET ISOLATION AND METHOD

(71) Applicant: Micron Technology, Inc., Boise, ID (US)

(72) Inventors: Jiewei Chen, Meridian, ID (US); Jordan D. Greenlee, Boise, ID (US); Sundar Rajarajan, San Jose, CA (US)

(21) Appl. No.: 19/279,582

(22) Filed: Jul. 24, 2025

Related U.S. Application Data
(60) Provisional application No. 63/677,646, filed on Jul. 31, 2024.

(51) Int. Cl. H01L 23/532; H01L 21/768; H01L 23/522; H01L 23/528; H10B 41/27; H10B 41/30; H10B 43/27; H10B 43/30

(52) U.S. Cl. CPC H01L 23/53257; H01L 21/76831; H01L 21/76877; H01L 23/5226; H01L 23/5283; H01L 23/53295; H10B 41/27; H10B 41/30; H10B 43/27; H10B 43/30

(57) ABSTRACT

Apparatus and methods are disclosed, including interconnection pathways, vias, memory cells, semiconductor devices and systems. Example semiconductor devices and methods include a conducting via passing between a top level of a stack and a bottom level of the stack. One or more isolation layers surround sides and a bottom of the conducting via. A lateral connection is shown between a location along the conducting via and a selected conductor layer from the stack, the lateral connection passing through the isolation layer.

### PRIORITY APPLICATION

This application claims the benefit of priority to U.S. Provisional Application Ser. No. 63/677,646, filed Jul. 31, 2024, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to transistor structures in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2A illustrates selected components of a memory device in a stage of manufacture in accordance with some example embodiments.

FIG. 2B illustrates selected components of a memory device in another stage of manufacture in accordance with some example embodiments.

FIG. 2C illustrates selected components of a memory device in another stage of manufacture in accordance with some example embodiments.

FIG. 2D illustrates selected components of a memory device in another stage of manufacture in accordance with some example embodiments.

FIG. 2E illustrates selected components of a memory device in another stage of manufacture in accordance with some example embodiments.

FIG. 3A illustrates selected components of a memory device in a stage of manufacture in accordance with some example embodiments.

FIG. 3B illustrates selected components of a memory device in another stage of manufacture in accordance with some example embodiments.

FIG. 4 illustrates an example method flow diagram in accordance with other example embodiments.

FIG. 5 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

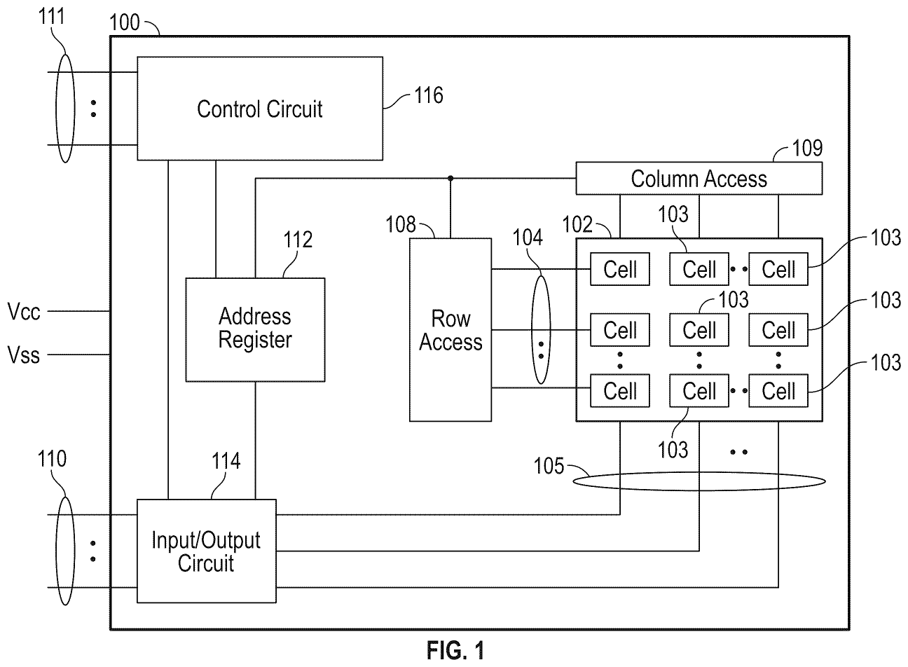

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

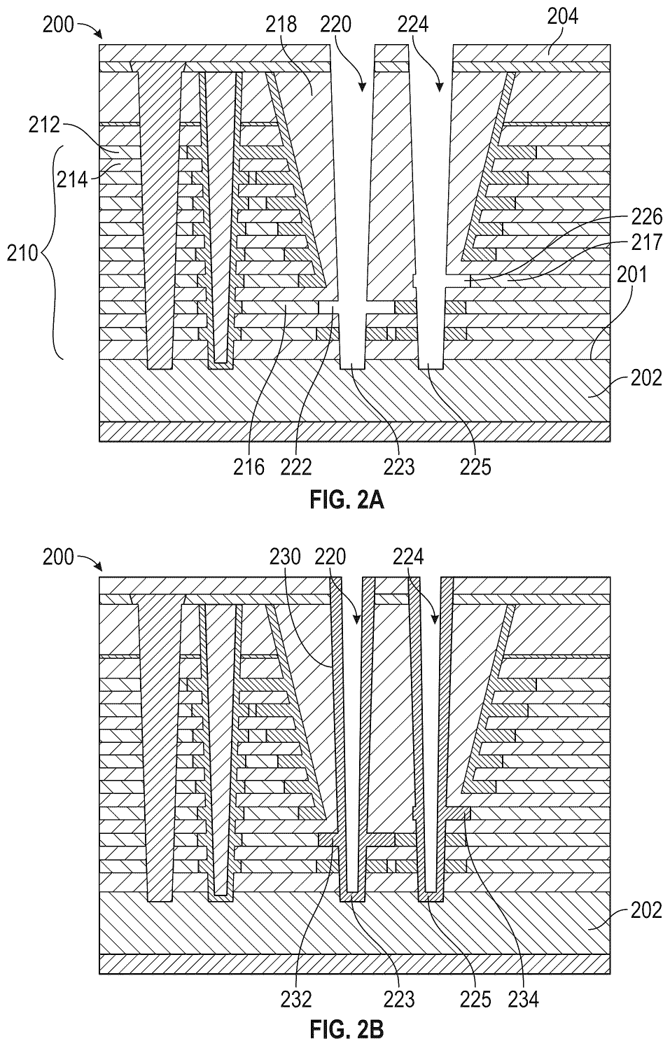

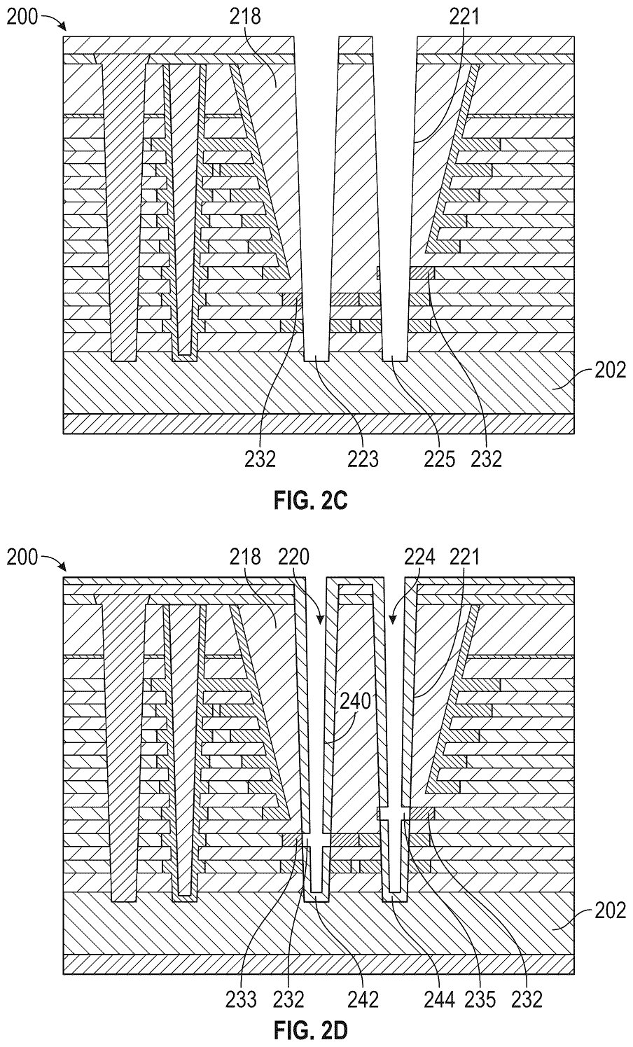

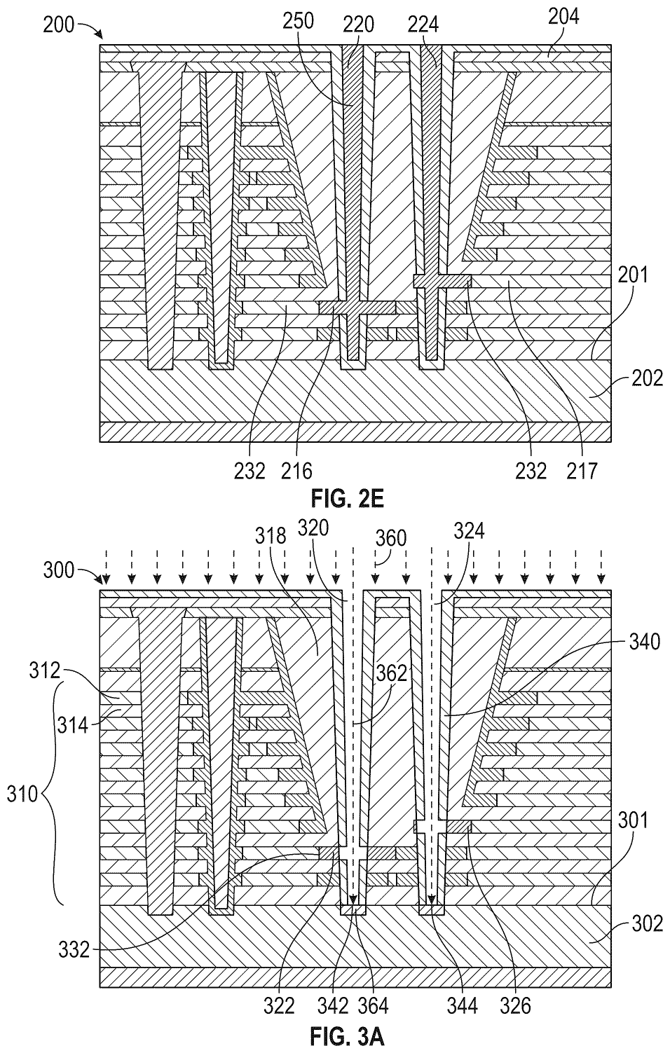

Memory cells 103 and other circuits 114, 116, etc. may include interconnection structures and utilize methods as described in more detail in FIGS. 2A-4. In one example, memory arrays 102 include RAM storage, and peripheral circuits such as circuits 114, 116, 108, 109, etc. may include transistors as described in more detail in FIGS. 2A-4. In one example, memory arrays 102 include NAND storage.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

FIG. 2A shows selected interconnection structures in a memory device 200. In one example, the interconnection structures are included in a staircase structure that is used to access vertical memory strings. In one example vertical memory strings include vertical NAND memory strings, although the invention is not so limited. Other types of memory devices, and/or other semiconductor devices also benefit from example configurations described.

A stack 210 of alternating dielectric layers 214 and conductor layers 212 is shown in FIG. 2A. In one example, the dielectric layers 214 include silicon oxide, although the invention is not so limited. In one example, the conductor layers 212 include tungsten.

A substrate 202 is located at a bottom level 201 of the stack 210. In one example, the substrate 202 includes polysilicon. In selected configurations, it is desirable to form a conducting via through the stack 210 from a top level 204 to the bottom level 201. Configurations shown further include a lateral connection from the conducting via to a selected conductor layer. FIGS. 2A-2E show selected stages of manufacturing to form a conducting via and a lateral connection.

In FIG. 2A, a first vertical cavity 220 is formed through the stack 210 of alternating dielectric layers and conductor layers. In the example of FIG. 2A, a surrounding dielectric 218 is further included between the dielectric layers 214 and conductor layers 212 and the first vertical cavity 220. In one example, the surrounding dielectric 218 includes silicon oxide. In one example, the surrounding dielectric 218 is shaped in a taper with a wider portion at the top level 204 and narrowing down at the bottom level 201. In the example of a staircase structure, the taper of the surrounding dielectric 218 facilitates access to selected conductor layers 212 at different levels of the stack 210. A second vertical cavity 224 is also shown in FIG. 2A.

The first vertical cavity 220 passes through the stack 210, and contacts or extends into the substrate 202. An exposed first base 223 of the first vertical cavity 220 is shown. A first lateral cavity 222 is formed, and is connected to the first vertical cavity 220. In the example shown, the first lateral cavity 222 extends away on all sides of the first vertical cavity 220 although the invention is not so limited. As discussed below with respect to the second vertical cavity 224, procedures such as selective etch provide examples where a lateral cavity only extends on one side of a vertical cavity, or where a lateral extension amount is different on different sides of a vertical cavity.

The second vertical cavity 224 passes through the stack 210, and also contacts or extends into the substrate 202. An exposed second base 225 of the second vertical cavity 224 is also shown. A second lateral cavity 226 is formed, and is connected to the second vertical cavity 224. As discussed above, the second lateral cavity 226 extends deeper on one side of the second vertical cavity 224 than on another. As shown in FIG. 2A, the first lateral cavity 222 exposes a portion of a first selected conductor layer 216 and the second lateral cavity 226 exposes a portion of a second selected conductor layer 217.

In FIG. 2B, the lateral cavities 222, 226 are filled with a second conductor material portion 232 in the first lateral cavity 222, and in the second lateral cavity 226. A second conductor material liner 230 is also formed on sidewalls of the vertical cavities 220, 224. In the example, shown both the second conductor material 232 and the second conductor material liner 230 are formed concurrently in a deposition operation. Examples of deposition include, but are not limited to, physical vapor deposition (PCD), chemical vapor deposition (CVD) etc. In one example, the second conductor material 232 and the second conductor material liner 230 both include tungsten.

In FIG. 2C, the second conductor material liner 230 is removed from the sidewalls of the vertical cavities 220, 224. An etch operation will remove material from the sidewalls at a greater rate than within the narrower lateral cavities 222, 226 due to differences in exposed surface area. By controlling an etch time, the second conductor material portions 232 remain within the lateral cavities 222, 226 while the second conductor material is removed from the sides of the vertical cavities 220, 224.

In FIG. 2D, an isolation material 240 is formed over the memory device 200. In FIG. 2D, an isolation material 240 is chosen that is selective with respect to deposition on the second conductor material 232 within the vertical cavities 220, 224. In one example, silicon oxycarbide is used as the isolation material 240. Although silicon oxycarbide is used as an example, other dielectric materials that exhibit selective deposition as described are also within the scope of the invention. In one example, the isolation material 240 is self-aligned due to the selective deposition.

In FIG. 2D, because the isolation material 240 forms more favorably on the surrounding dielectric 218 and the substrate 202, and forms less favorably on the second conductor material 232, a first recess 233 is created adjacent to the second conductor material 232 in the first lateral cavity 222. Likewise, a second recess 235 is created adjacent to the second conductor material 232 in the second lateral cavity 226. A first bottom 242 of the first vertical cavity 220, and a second bottom 244 of the second vertical cavity 224 are covered with the isolation material 240.

In one example, selective deposition alone provides the recesses 233, 235. In one example, after selective deposition, an etch is performed after deposition of the isolation material 240, and any isolation material 240 deposited in the recesses 233, 235 is thinner than isolation material 240 on surrounding dielectric 218 and the substrate 202, therefore an etch is timed to remove all isolation material 240 from within recesses 233, 235, while leaving a layer of isolation material 240 on the surrounding dielectric 218 and the substrate 202.

In FIG. 2E, a third conductor 250 is deposited within the first vertical cavity 220 and the second vertical cavity 224. In one example, the third conductor 250 is the same conductor material as the second conductor material 232, although the invention is not so limited. In one example, the third conductor 250 includes tungsten. In one example, the third conductor 250 is self-aligned due to the selective deposition of the isolation material 240.

The third conductor 250 forms an electrical connection from the vertical cavities 220, 224, through the lateral cavities 222, 226 and into selected conductor layers 216, 217. The isolation material 240 provides electrical isolation between the vertical cavities 220, 224 and the substrate 202. In one example it is desired to provide a level of electrical isolation between the vertical cavities 220, 224 and the substrate for a number of advantages. One advantage includes quality control during manufacture. When the vertical cavities 220, 224 are electrically isolated from the substrate 202, electrical testing for defects in manufacturing is facilitated. Conditions such as word line leakage and electrical opens are more easily tested when conductors in vertical cavities 220, 224 are electrically isolated from the substrate 202.

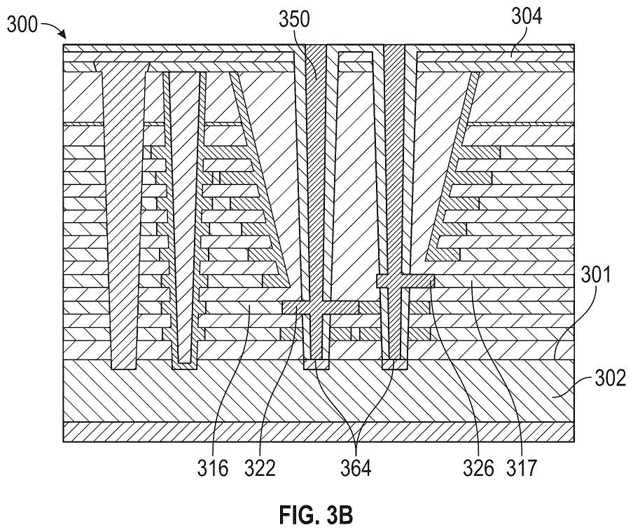

FIGS. 3A-3B show another configuration of a memory device 300. Similar to the example of FIGS. 2A-2E, in one example, interconnection structures are included in a staircase structure that is used to access vertical memory strings. A stack 310 of alternating dielectric layers 314 and conductor layers 312 is shown in FIG. 3A. A substrate 302 is located at a bottom level 301 of the stack 310.

A first isolation material 340 is shown within a first vertical cavity 320 and a second vertical cavity 324. Similar to the example of FIGS. 2A-2E, the first isolation material 340 covers sidewalls of the first vertical cavity 320 and the second vertical cavity 324, and does not cover a second conductor material 332 in a first lateral cavity 322 and a second lateral cavity 326. As described in examples above, a first isolation material 340 is chosen that is selective in deposition, and forms the configuration shown in FIG. 3A similar to the configuration shown in FIG. 2D.

In FIG. 3A, the first isolation material 340 covers a bottom 342 of the first vertical cavity 320 and a bottom 344 of the second vertical cavity 324. The first isolation material 340 is converted to a second isolation material 364 at the bottoms 342, 344 of the vertical cavities 320, 324. In one example, a conversion process includes an implant as shown by arrows 360. As a result of a directional implant as shown by arrow 362, only bottoms 342, 344 of the vertical cavities 320, 324 are converted to the second isolation material 364, while sidewalls of the vertical cavities 320, 324 remain covered by the first isolation material 340.

In FIG. 3B, a third conductor 350 is deposited within the first vertical cavity 320 and the second vertical cavity 324. In one example, the third conductor 250 is the same conductor material as the second conductor material 332, although the invention is not so limited. In one example, the third conductor 350 includes tungsten. The third conductor 350 forms an electrical connection from the vertical cavities 320, 324, through the lateral cavities 322, 326 and into selected conductor layers 316, 317. The second isolation material 364 provides electrical isolation between the vertical cavities 320, 324 and the substrate 302.

As noted above, in one example it is desired to provide a level of electrical isolation between the vertical cavities 220, 224 and the substrate. In one example, the inclusion of a second isolation material 364 provides control over an amount of electrical isolation. The second isolation material 364 is selected for its' dielectric constant, that may be different than the first isolation material 340. In this way, an increased level of electrical isolation is provided by selecting a second isolation material 364 having a higher dielectric constant from the first isolation material 340, or having a higher thickness from the first isolation material 340. In one example, the second isolation material 364 includes silicon oxide, although the invention is not so limited.

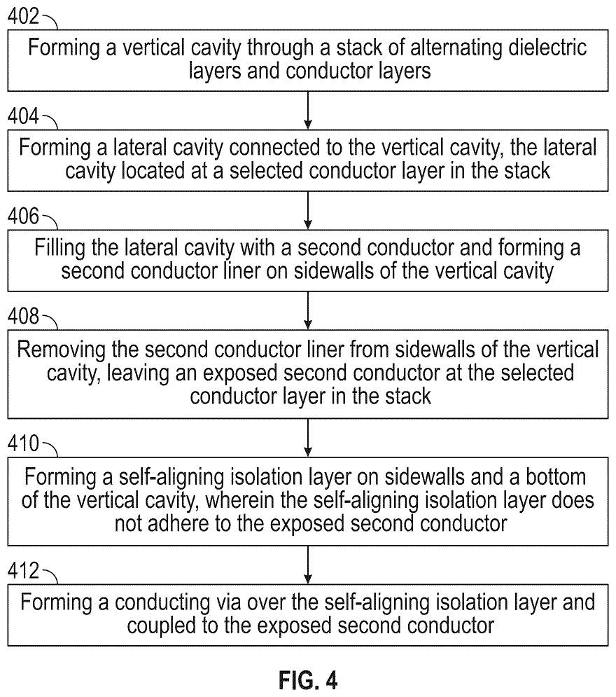

FIG. 4 shows a flow diagram of an example method of manufacture. In operation 402, a vertical cavity is formed through a stack of alternating dielectric layers and conductor layers. In operation 404, a lateral cavity is formed where the lateral cavity is connected to the vertical cavity and the lateral cavity is located at a selected conductor layer in the stack. In operation 406, the lateral cavity is filled with a second conductor and a second conductor liner is formed on sidewalls of the vertical cavity. In operation 408, the second conductor liner is removed from sidewalls of the vertical cavity, leaving an exposed second conductor at the selected conductor layer in the stack. In operation 410, a self-aligning isolation layer is formed on sidewalls and a bottom of the vertical cavity, wherein the self-aligning isolation layer does not adhere to the exposed second conductor. Lastly, in operation 412, a conducting via is formed over the self-aligning isolation layer and coupled to the exposed second conductor.

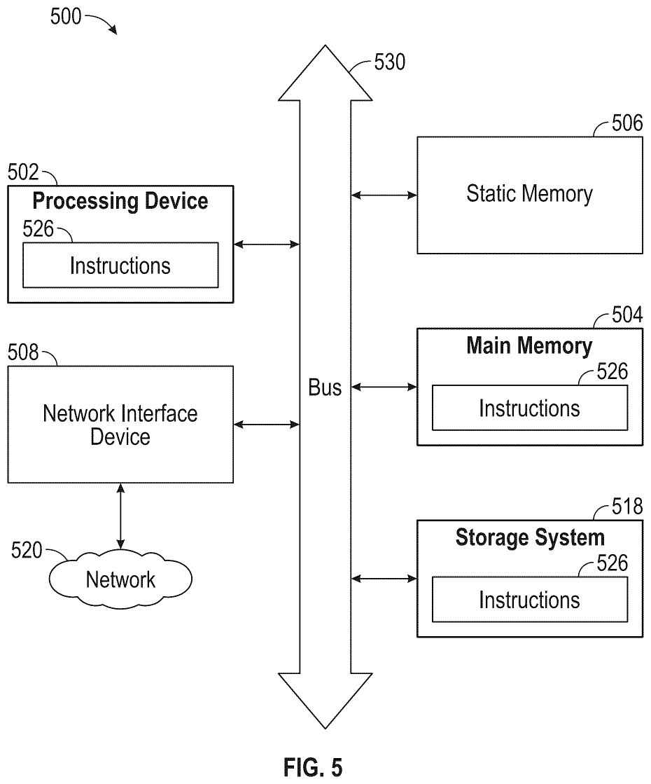

FIG. 5 illustrates a block diagram of an example machine (e.g., a host system) 500 which may include one or more interconnection structures, staircase structures, memory devices and/or memory systems as described above. As discussed above, machine 500 may benefit from enhanced memory performance from use of one or more of the described transistor structures and/or memory systems, facilitating improved performance of machine 500 (as for many such machines or systems, efficient reading and writing of memory can facilitate improved performance of a processor or other components that machine, as described further below.

In alternative embodiments, the machine 500 may operate as a standalone device or may be connected (e.g., networked) to other machines. In a networked deployment, the machine 500 may operate in the capacity of a server machine, a client machine, or both in server-client network environments. In an example, the machine 500 may act as a peer machine in peer-to-peer (P2P) (or other distributed) network environment. The machine 500 may be a personal computer (PC), a tablet PC, a set-top box (STB), a personal digital assistant (PDA), a mobile telephone, a web appliance, an loT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 500 may include a processing device 502 (e.g., a hardware processor, a central processing unit (CPU), a graphics processing unit (GPU), a hardware processor core, or any combination thereof, etc.), a main memory 504 (e.g., read-only memory (ROM), dynamic random-access memory (DRAM) such as synchronous DRAM (SDRAM) or Rambus DRAM (RDRAM), etc.), a static memory 506 (e.g., static random-access memory (SRAM), etc.), and a storage system 518, some or all of which may communicate with each other via a communication interface (e.g., a bus) 530. In one example, the main memory 504 includes one or more memory devices as described in examples above.

The processing device 502 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 502 can also be one or more special-purpose processing devices such as an application specific integrated circuit (ASIC), a field programmable gate array (FPGA), a digital signal processor (DSP), network processor, or the like. The processing device 502 can be configured to execute instructions 526 for performing the operations and steps discussed herein. The computer system 500 can further include a network interface device 508 to communicate over a network 520.

The storage system 518 can include a machine-readable storage medium (also known as a computer-readable medium) on which is stored one or more sets of instructions 526 or software embodying any one or more of the methodologies or functions described herein. The instructions 526 can also reside, completely or at least partially, within the main memory 504 or within the processing device 502 during execution thereof by the computer system 500, the main memory 504 and the processing device 502 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 500 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 500 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 526 (e.g., software, programs, an operating system (OS), etc.) or other data are stored on the storage system 518 can be accessed by the main memory 504 for use by the processing device 502. The main memory 504 (e.g., DRAM) is typically fast, but volatile, and thus a different type of storage than the storage system 518 (e.g., an SSD), which is suitable for long-term storage, including while in an “off” condition. The instructions 526 or data in use by a user or the machine 500 are typically loaded in the main memory 504 for use by the processing device 502. When the main memory 504 is full, virtual space from the storage system 518 can be allocated to supplement the main memory 504; however, because the storage system 518 device is typically slower than the main memory 504, and write speeds are typically at least twice as slow as read speeds, use of virtual memory can greatly reduce user experience due to storage system latency (in contrast to the main memory 504, e.g., DRAM). Further, use of the storage system 518 for virtual memory can greatly reduce the usable lifespan of the storage system 518.

The instructions 526 may further be transmitted or received over a network 520 using a transmission medium via the network interface device 508 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 508 may include one or more physical jacks (e.g., Ethernet, coaxial, or phone jacks) or one or more antennas to connect to the network 520. In an example, the network interface device 508 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 500, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:
Aspect 1. A memory device, comprising; a stack of alternating dielectric layers and conductor layers; a number of memory cells formed within the stack of alternating dielectric layers and conductor layers; a conducting via passing between a top level of the stack and a bottom level of the stack; an isolation layer surrounding sides and a bottom of the conducting via; and a lateral connection between a location along the conducting via and a selected conductor layer from the stack, the lateral connection passing through the isolation layer.
Aspect 2. The memory device of aspect 1, wherein the number of memory cells includes a number of NAND memory strings.
Aspect 3. The memory device of aspect 1, wherein the conducting via is included in a staircase access structure for a NAND memory array.
Aspect 4. The memory device of aspect 1, wherein the conducting via includes tungsten.
Aspect 5. The memory device of aspect 1, wherein the isolation layer includes silicon oxycarbide.
Aspect 6. The memory device of aspect 1, wherein the conducting via and the isolation layer are through silicon oxide.
Aspect 7. The memory device of aspect 1, wherein the lateral connection includes tungsten.
Aspect 8. A memory device, comprising; a stack of alternating dielectric layers and conductor layers; a number of memory cells formed within the stack of alternating dielectric layers and conductor layers; a conducting via passing between a top level of the stack and a bottom level of the stack; a first isolation layer surrounding sides of the conducting via; a second isolation layer between a bottom of the conducting via and a substrate; and a lateral connection between a location along the conducting via and a selected conductor layer from the stack, the lateral connection passing through the first isolation layer.
Aspect 9. The memory device of aspect 8, wherein the number of memory cells includes a number of NAND memory strings.
Aspect 10. The memory device of aspect 8, wherein the conducting via is included in a staircase access structure for a NAND memory array.
Aspect 11. The memory device of aspect 8, wherein the conducting via includes tungsten.
Aspect 12. The memory device of aspect 8, wherein the first isolation layer includes silicon oxycarbide.
Aspect 13. The memory device of aspect 12, wherein the second isolation layer includes silicon oxide.
Aspect 14. The memory device of aspect 13, wherein the conducting via and the first isolation layer are through silicon oxide.
Aspect 15. The memory device of aspect 14, wherein the second isolation layer contacts a polysilicon base beneath the stack of alternating dielectric layers and conductor layers.
Aspect 16. The memory device of aspect 8, wherein the lateral connection includes tungsten.
Aspect 17. A method of forming a memory device, comprising: forming a vertical cavity through a stack of alternating dielectric layers and conductor layers; forming a lateral cavity connected to the vertical cavity, the lateral cavity located at a selected conductor layer in the stack; filling the lateral cavity with a second conductor and forming a second conductor liner on sidewalls of the vertical cavity; removing the second conductor liner from sidewalls of the vertical cavity, leaving an exposed second conductor at the selected conductor layer in the stack; forming a self-aligning isolation layer on sidewalls and a bottom of the vertical cavity, wherein the self-aligning isolation layer does not adhere to the exposed second conductor; and forming a conducting via over the self-aligning isolation layer and coupled to the exposed second conductor.
Aspect 18. The method of aspect 17, wherein the forming the self-aligning isolation layer includes forming a silicon oxycarbide layer on sidewalls and a bottom of the vertical cavity wherein the silicon oxycarbide layer is selectively non-adherent to the selected conductor.
Aspect 19. The method of aspect 17, wherein filling the lateral cavity with the second conductor includes filling the lateral cavity with a conductor including tungsten.
Aspect 20. The method of aspect 17, wherein forming the conducting via includes filling in the vertical cavity with a third conductor including tungsten.
Aspect 21. The method of aspect 17, further including converting a bottom of the self-aligning isolating layer to silicon oxide prior to forming the conducting via.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A memory device, comprising;
a stack of alternating dielectric layers and conductor layers;
a number of memory cells formed within the stack of alternating dielectric layers and conductor layers;
a conducting via passing between a top level of the stack and a bottom level of the stack;
an isolation layer surrounding sides and a bottom of the conducting via; and
a lateral connection between a location along the conducting via and a selected conductor layer from the stack, the lateral connection passing through the isolation layer.

2. The memory device of claim 1, wherein the number of memory cells includes a number of NAND memory strings.

3. The memory device of claim 1, wherein the conducting via is included in a staircase access structure for a NAND memory array.

4. The memory device of claim 1, wherein the conducting via includes tungsten.

5. The memory device of claim 1, wherein the isolation layer includes silicon oxycarbide.

6. The memory device of claim 1, wherein the conducting via and the isolation layer are through silicon oxide.

7. The memory device of claim 1, wherein the lateral connection includes tungsten.

8. A memory device, comprising;
a stack of alternating dielectric layers and conductor layers;
a number of memory cells formed within the stack of alternating dielectric layers and conductor layers;
a conducting via passing between a top level of the stack and a bottom level of the stack;
a first isolation layer surrounding sides of the conducting via;
a second isolation layer between a bottom of the conducting via and a substrate; and
a lateral connection between a location along the conducting via and a selected conductor layer from the stack, the lateral connection passing through the first isolation layer.

9. The memory device of claim 8, wherein the number of memory cells includes a number of NAND memory strings.

10. The memory device of claim 8, wherein the conducting via is included in a staircase access structure for a NAND memory array.

11. The memory device of claim 8, wherein the conducting via includes tungsten.

12. The memory device of claim 8, wherein the first isolation layer includes silicon oxycarbide.

13. The memory device of claim 12, wherein the second isolation layer includes silicon oxide.

14. The memory device of claim 13, wherein the conducting via and the first isolation layer are through silicon oxide.

15. The memory device of claim 14, wherein the second isolation layer contacts a polysilicon base beneath the stack of alternating dielectric layers and conductor layers.

16. The memory device of claim 8, wherein the lateral connection includes tungsten.

17. A method of forming a memory device, comprising:
forming a vertical cavity through a stack of alternating dielectric layers and conductor layers;
forming a lateral cavity connected to the vertical cavity, the lateral cavity located at a selected conductor layer in the stack;
filling the lateral cavity with a second conductor and forming a second conductor liner on sidewalls of the vertical cavity;
removing the second conductor liner from sidewalls of the vertical cavity, leaving an exposed second conductor at the selected conductor layer in the stack;
forming a self-aligning isolation layer on sidewalls and a bottom of the vertical cavity, wherein the self-aligning isolation layer does not adhere to the exposed second conductor; and
forming a conducting via over the self-aligning isolation layer and coupled to the exposed second conductor.

18. The method of claim 17, wherein the forming the self-aligning isolation layer includes forming a silicon oxycarbide layer on sidewalls and a bottom of the vertical cavity wherein the silicon oxycarbide layer is selectively non-adherent to the selected conductor.

19. The method of claim 17, wherein filling the lateral cavity with the second conductor includes filling the lateral cavity with a conductor including tungsten.

20. The method of claim 17, wherein forming the conducting via includes filling in the vertical cavity with a third conductor including tungsten.

21. The method of claim 17, further including converting a bottom of the self-aligning isolating layer to silicon oxide prior to forming the conducting via.
